(19) United States
(12) Patent Application Publication
(10) Pub. No.: US 2008/0296589 A1
(43) Pub. Date: Dec. 4, 2008

(54) Solid-State Lighting Device Package

(76) Inventors: Ingo Speier, Vancouver (CA); Philippe Schick, Vancouver (CA)

Correspondence Address: PHILIPS INTELLECTUAL PROPERTY & STANDARDS, 3 BURLINGTON WOODS DRIVE, BURLINGTON, MA, 01803, US

(21) Appl. No.: 10/582,565

(22) PCT Filed: Mar. 24, 2006
(86) PCT No.: PCT/CA06/00442

§ 371 Date: Sep. 6, 2006

Related U.S. Application Data
(60) Provisional application No. 60/665,179, filed on Mar. 24, 2005.

(30) Foreign Application Priority Data
Feb. 10, 2006 (CA) 2535958

(51) Int. Cl. H01L 33/00

(52) U.S. Cl. 257/82; 257/98; 257/E33.001

(57) ABSTRACT

The present invention provides a lighting device package, which can provide a means for efficient thermal access to the lighting device package in addition to a desired level of light extraction from the one or more light-emitting elements within the lighting device package. The lighting device package comprises a substrate having a thermally conductive region to which one or more light-emitting elements are thermally connected, wherein the light-emitting elements may be relatively closely packed. An optical system is optically coupled to one or more light emitting elements, and is positioned relative to the substrate such that the optical system substantially encloses the one or more light-emitting elements on the substrate. The optical system is adapted to extract the light from the one or more light-emitting elements.

### FIELD OF THE INVENTION

The present invention pertains to the field of lighting and in particular to solid-state lighting device packages.

### BACKGROUND

Advances in the development and improvements of the luminous flux of light-emitting devices such as solid-state semiconductor and organic light-emitting diodes (LEDs) have made these devices suitable for use in general illumination applications, including architectural, entertainment, and roadway lighting. Light-emitting diodes are becoming increasingly competitive with light sources such as incandescent, fluorescent, and high-intensity discharge lamps.

Light-emitting diodes offer a number of advantages and are generally chosen for their ruggedness, long lifetime, high efficiency, low voltage requirements, and the possibility to control the colour and intensity of the emitted light independently. They provide an improvement over delicate gas discharge lamp, incandescent or fluorescent lighting systems. Solid-state semiconductor and improvingly organic light-emitting diodes have the capability to create the same outstanding lighting impressions but greatly outweigh the drawbacks associated with the other lighting technologies.

Unlike classical incandescent light sources which can emit almost all of the generated waste heat in the form of infrared radiation, most of the heat generated in LEDs is first absorbed by the material structures comprising the optically and electrically active regions inside the die. The die itself therefore obstructs heat transfer to the environment. Despite the higher electro-optical conversion efficiency, thermal management is of particular relevance in LED luminaire design. The efficiency and longevity of light-emitting diodes is strongly affected by device temperature and hence LEDs demand sophisticated combinations of passive or active cooling mechanisms in order to maintain acceptable operating temperature conditions. For fixed parameters such as packaging and employed die materials, factors of aging such as the durability and reliability of light-emitting diodes are substantially governed by operating temperature conditions.

In this respect, package design for use with solid-state lighting devices is of particular importance in providing a means for managing the device operating temperature effectively in addition to providing for a desired level of light extraction from the solid-state lighting device itself.

U.S. Pat. No. 6,617,795 provides a multi-chip light-emitting-diode package having a support member, at least two light-emitting-diode chips disposed on the support member, at least one sensor disposed on the support member for reporting quantitative and spectral information to a controller, relating to the light output of the light-emitting-diodes, and a signal processing circuit, including an analog-to-digital converter logic circuit, disposed on the support member for converting the analog signal output produced by the sensors to a digital signal output. This patent however, does not provide ease of thermal access for thermal extraction of heat generated by the multi-chip light-emitting-diode package.

A light emitting die package is disclosed in United States Patent Application Publication No. 2004/0041222. The die package includes a substrate, a reflector plate, and a lens. The substrate is made from thermally conductive but electrically insulating material. The substrate has traces for connecting an external electrical power source to a light emitting diode (LED) at a mounting pad. The reflector plate is coupled to the substrate and substantially surrounds the mounting pad. The lens is free to move relative to the reflector plate and is capable of being raised or lowered by the encapsulant that wets and adheres to it and is placed at an optimal distance from the LED chips. The lens can be coated with any optical system of chemical that affects the performance of the device. Heat generated by the LED during operation is drawn away from the LED by both the substrate and the reflector plate act as a heat sink. The reflector plate includes a reflective surface to direct light from the LED in a desired direction.

In addition, U.S. Pat. No. 6,707,069 provides a LED package, made of ceramic substrates and having a reflective metal plate, a first ceramic substrate, which has a chip mounting area on its top surface, and is provided with a predetermined conductive pattern formed around the chip mounting area. One or more LED chips are seated on the chip mounting area of the first ceramic substrate, and are connected to the conductive pattern. A second ceramic substrate is mounted on the top surface of the first ceramic substrate and has a cavity at a position corresponding to the chip mounting area. The reflective metal plate is set in the cavity of the second ceramic substrate to surround the LED chips. The reflective metal plate acts as a heat sink for dissipating heat from the LED chips.

U.S. Pat. No. 6,949,771 discloses a light source suitable for surface mounting onto a printed circuit board. The light source includes a planar substrate with a centrally positioned aperture. A light emitting diode is mounted on a metallic layer covering the bottom of the aperture, and is encapsulated by a transparent encapsulation material. The metallic layer provides a thermal path for heat generated by the light emitting diode.

An LED module is disclosed in U.S. Pat. No. 6,860,621. The LED module includes a relatively thick substrate having good thermal conductivity and one or more radiation-emitting semiconductor components that fixed on the top side of the substrate. The underside of the substrate is fixed on a carrier body having a high thermal capacity, in which the component fixing between the semiconductor components and the substrate and the substrate fixing between the substrate and the carrier body are embodied with good thermal conductivity.

U.S. Pat. No. 6,858,870 discloses a multi-chip light emitting diode (LED) package which includes red, green, and blue LED chips directly bonded on a silicon substrate for a controlling integrated circuit (IC), and a relatively thick carrier to which the controlling IC is attached. The multi-chip LED package has reduced volume and enhanced heat-radiating power. The chips are directly driven and controlled by the controlling IC, so that the carrier is not necessarily a printed circuit board but may be made of any solid material.

A white light emitting LED luminaire is disclosed in U.S. Pat. No. 6,741,351. The LED luminaire incorporates an array of red, green and blue emitting LEDs and a feedback arrangement to maintain a desired color balance. The feedback arrangement includes photodiodes positioned and enabled to separately measure the light output of each RGB color component. Individual colors are measured sequentially by pulsing the LEDs and photodiodes or by the use of color filters.

U.S. Pat. No. 6,498,355 discloses a light emitting diode array with a relatively complicated construction, which includes a metal substrate, a dielectric layer disposed above the metal substrate, and a plurality of electrically conductive traces disposed on the dielectric layer. A plurality of vias pass through the dielectric layer. The light emitting diode array also includes a plurality of light emitting diodes, each of which is disposed above a corresponding one of said vias and each of which includes a first electrical contact and a second electrical contact electrically coupled to separate ones of the electrically conductive traces. Each of the vias contains a thermally conductive material in thermal contact with the metal substrate and in thermal contact with the corresponding light emitting diode.

While some thermal issues relating to LED operation are considered in the prior art, there is a need for a new solid-state lighting package that can provide both a desired level of thermal access to the solid-state lighting device enabling heat extraction together with a desired level of light extraction from the lighting package, while reducing the number of parts.

This background information is provided to reveal information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a solid-state lighting device package. In accordance with an aspect of the present invention, there is provided a lighting device package comprising: a substrate including a thermally conductive region; one or more light-emitting elements mounted on the substrate to provide thermal connectivity between the one or more light-emitting elements and the thermally conductive region, the one or more light-emitting elements for generating light; and an optical system coupled to the substrate and configured to substantially enclose the one or more light-emitting elements on the substrate, the optical system adapted to extract the light from the one or more light-emitting elements; wherein the lighting device package is adapted for connection to a means for controlling activation of the one or more light-emitting elements.

### BRIEF DESCRIPTION OF THE FIGURES

FIG. 1 illustrates a lighting device package according to one embodiment of the present invention.

FIG. 2A is a perspective view of a substrate and connected light-emitting elements according to one embodiment of the present invention.

FIG. 2B is a top view of the substrate illustrated in FIG. 2A.

FIG. 2C is a bottom view of the substrate illustrated in FIG. 2A.

FIG. 3 is a perspective view of a substrate and connected light-emitting elements and an optical sensor according to one embodiment of the present invention.

FIG. 4 is a top view of a substrate with connected light-emitting elements, an optical sensor and thermal sensors according to one embodiment of the present invention.

FIG. 5 is a top view of a substrate with four light-emitting elements connected thereto according to one embodiment of the present invention.

FIG. 6 is a top view of the embodiment of FIG. 5, wherein a dome lens encloses the light-emitting elements.

FIG. 7 is a cross sectional view of a lighting device package according to another embodiment of the present invention.

FIG. 8 is a cross sectional view of the lighting device package of FIG. 7, coupled to a heat pipe and PCB boards.

FIG. 9 illustrates a lighting device package according to another embodiment of the present invention.

FIG. 10 illustrates a lighting device package according to another embodiment of the present invention.

FIG. 11 illustrates paths of light propagation for a lighting device package according to one embodiment of the present invention.

FIG. 12 is a cross sectional view of a lighting device package according to one embodiment of the present invention.

FIG. 13 is a cross sectional view of a lighting device package configured as a ball grid array (BGA) package according to one embodiment of the present invention.

FIG. 14 is a cross sectional view of a lighting device package similar to FIG. 13 but configured as a quad flat pack (QFP) package according to another embodiment of the present invention.

FIG. 15A is a cross sectional view of multiple lighting device packages configured as a quad flat pack (QFP) package according to one embodiment of the present invention.

FIG. 15B is a cross sectional view of lighting device packages configured as a quad flat pack (QFP) package mounted on a printed circuit board and connected to heat pipes, according to one embodiment of the present invention.

### DETAILED DESCRIPTION OF THE INVENTION

### Definitions

The term “light-emitting element” is used to define any device that emits radiation in any region or combination of regions of the electromagnetic spectrum for example, the visible region, infrared and/or ultraviolet region, when activated by applying a potential difference across it or passing a current through it, for example. Therefore a light-emitting element can have monochromatic, quasi-monochromatic, polychromatic or broadband spectral emission characteristics. Examples of light-emitting elements include semiconductor, organic, or polymer/polymeric light-emitting diodes, optically pumped phosphor coated light-emitting diodes, optically pumped nano-crystal light-emitting diodes or any other similar light-emitting devices as would be readily understood by a worker skilled in the art.

The term “thermally conductive element” is used to define an element providing a means for thermal energy transfer. A thermally conductive element can be designed to incorporate thermal removal techniques including but not limited to, liquid cooling, evaporative cooling, heat pipes, thermosyphons, thermoelectrics, thermotunnels, heat spreaders, and heat sinks.

As used herein, the term “about” refers to a +/−10% variation from the nominal value. It is to be understood that such a variation is always included in any given value provided herein, whether or not it is specifically referred to.

Unless defined otherwise, all technical and scientific terms used herein have the same meaning as commonly understood by one of ordinary skill in the art to which this invention belongs.

The present invention provides a lighting device package, which can provide a means for enhanced thermal access to the package enabling heat extraction there from, in addition to a desired level of light extraction from the one or more light-emitting elements within the lighting device package. The lighting device package comprises a substrate including a thermally conductive region, wherein one or more light-emitting elements are thermally connected to the thermally conductive region and can be relatively closely packed relative to each other. An optical system is optically coupled to the one or more light emitting elements, and is positioned relative to the substrate such that the optical system substantially encloses the one or more light-emitting elements on the substrate. The optical system is adapted to extract the light from the one or more light-emitting elements and can be configured to extract the light at a relatively small aperture. In accordance with one embodiment of the present invention, the number of components necessary to fabricate the lighting device package can be minimized in order to simplify manufacture thereof.

In one embodiment, the thermally conductive region of the substrate of the lighting device package is adapted for intimate thermal connection to a thermally conductive element enabling a substantially enhanced level of thermal extraction from the light device package. Thermal regulation of the operational temperatures of the lighting device package can provide a means for increasing the density of light-emitting elements within the lighting device package thereby increasing the luminous flux output of the lighting device package. In addition, the thermal regulation may enable the inclusion of further electronic components within the lighting device package, wherein these further electronic components may be temperature sensitive.

In one embodiment, the lighting device package further comprises one or more sensors disposed on the substrate, wherein one or more sensors can collect information representative of predetermined operating conditions of the one or more light-emitting elements. This information can be subsequently relayed to a controller that can regulate the operation of the light-emitting elements in order to enable desired operation thereof. For example, the one or more sensors can be configured detect information relating to the light generated by the one or more light-emitting elements and/or the operational temperature of the lighting device package or one or more light-emitting elements.

In one embodiment of the present invention, the lighting device package further comprises one or more secondary optical elements that can provide a means for manipulating the illumination generated by the light-emitting elements. A secondary optical element can provide a means for re-directing the illumination in a desired direction and/or can provide a means for mixing the illumination generated by the one or more light-emitting elements or a combination thereof.

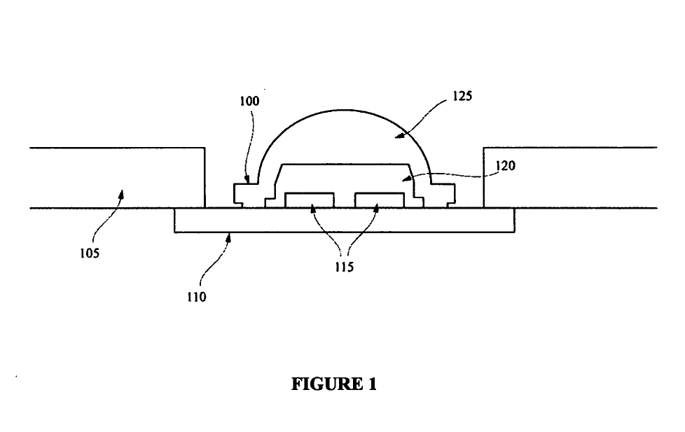

FIG. 1 illustrates a lighting device package according to one embodiment of the present invention. The lighting device package comprises a substrate 110, configured as a thermally conductive substrate, to which are thermally connected light-emitting elements 115. The lighting device package further comprises an optical system formed from a dome shaped lens 125 and an encapsulation material or encapsulant 120, wherein the optical system substantially encloses the light-emitting elements 115. In this embodiment the space between the light-emitting elements and the dome lens 125 is filled with the encapsulant 120, such as an optical silicone, for example. The encapsulant 120 can have an index of refraction as close as possible to the light-emitting elements to enhance light extraction.

### Substrate

The substrate provides a medium upon which one or more light-emitting elements can be positioned. The substrate is constructed such that a thermally conductive region is provided which may be adapted to provide intimate thermal connection to a thermally conductive element. By positioning the one or more light-emitting elements proximate to the thermally conductive region of the substrate, the heat generated by the light-emitting elements during operation, may be transferred away from the lighting package though a thermally conductive element.

In one embodiment, the thermally conductive region of the substrate can be configured to be relatively thin, thereby reducing the thermally conductive region's thermal resistance to heat transfer. For example the thermally conductive region can be between one-half and five times the thickness of a light-emitting elements associated therewith. In another embodiment the thermally conductive region can be between one and three times the thickness of a light-emitting elements and in another embodiment, the thermally conductive region thickness is less than two times that of a light-emitting element.

The substrate can be fabricated from a number of different materials, provided that the substrate comprises a thermally conductive region which may provide a means for intimate thermal connection to a thermally conductive element.

In one embodiment, the substrate can comprise two parts, namely a carrier portion and a thermally conductive portion. The substrate is configured for ease of thermal access to the thermally conductive portion. For example, the carrier portion can be a silicon layer upon which is formed a layer of CVD diamond or other thermally conductive material for example a thermally conductive ceramic selected from AlN, BeO, Alumina or other ceramic as would be readily understood by a worker skilled in the art, which forms the thermally conductive portion. In addition, alternate thermally conductive materials may be used for example monolithic carbonaceous materials, metal matrix composites (MMCs), carbon/carbon composites (CCCs), ceramic matrix composites (CMCs), polymer matrix composites (PMCs), and advanced metallic alloys. The one or more layers of thermal conductive material can provide the thermally conductive region to which the one or more light-emitting elements can be disposed. It would be readily understood that the silicon layer can be replaced by one or more layers of material that would be compatible with the lighting package, for example GaAs, GaN, AlGaS and InP.

In one embodiment of the present invention, the substrate is made entirely of one or more thermally conductive materials, for example, ceramic, for example AlN, Al₂O₃, BeO, metal core printed circuit board (MCPCB), direct bond copper (DBC), CVD diamond or other suitable thermally conductive material as would be known to a worker skilled in the art. Furthermore the substrate can be fabricated from a metal, for example Olin 194, Cu, CuW or any other thermally conductive alloy. The substrate may be coated with a dielectric for electrical isolation of one or more light-emitting elements, and/or electrical contacts. In one embodiment, electrical traces can be deposited onto dielectric coated substrate to allow electrical connectivity.

In one embodiment, the substrate can be designed with circuit traces providing electrical connections to the one or more light-emitting elements attached thereto. Alternately, the electrical connections can be provided on both sides of the substrate. In another embodiment, the substrate can be designed to comprise multiple electrically conducting planes in order to reduce the required circuit traces or other electrical connections, for example.

The substrate can be flat, curved or configured to have any other desired shape.

In one embodiment of the present invention, the substrate is formed with a depression a central region for the positioning of the one or more light-emitting elements. The vertical or angled walls of the depression can be formed as a reflective surface thereby providing a means for further light extraction from the one or more light-emitting elements.

In one embodiment of the present invention, the side of the substrate facing the emitting surface of the lighting device package can be optically active. For example this surface of the substrate can be reflective in order to further enhance light extraction from the one or more light-emitting elements.

In one embodiment of the present invention, the substrate can provide a means for ease of thermal connection to a thermally conductive element, for example a heat sink, heat pipe, thermosyphon and other thermal management systems as would be known to a worker skilled in the art. For example, the substrate can be configured in order that a thermally conductive element can be provided with intimate thermal contact with the thermally conductive region of the substrate.

In another embodiment, the substrate can be mounted on a side of the heat pipe enabling thermal transmission from the light-emitting elements to either or both ends of the heat pipe. As would be readily understood, the substrate can comprise one or more thermally conductive regions and the substrate can be configured to interconnect to one or more thermally conductive elements.

In one embodiment, the connection between the substrate and the thermally conductive element can be determined based on the type of thermally conductive element being used. For example, if the thermally conductive element is a heat pipe, the substrate can comprise a blind bore into which the heat pipe can be inserted, wherein the blind bore provides a means for intimate thermal connection to the one or more light-emitting elements via the thermally conductive region.

In one embodiment of the present invention, intimate thermal contact between the thermally conductive region and the thermally conductive element can be enhanced by the use of a thermal grease, thermal transfer film or thermally conductive epoxy or solder, or other thermal transfer enhancement means as would be known to a worker skilled in the art.

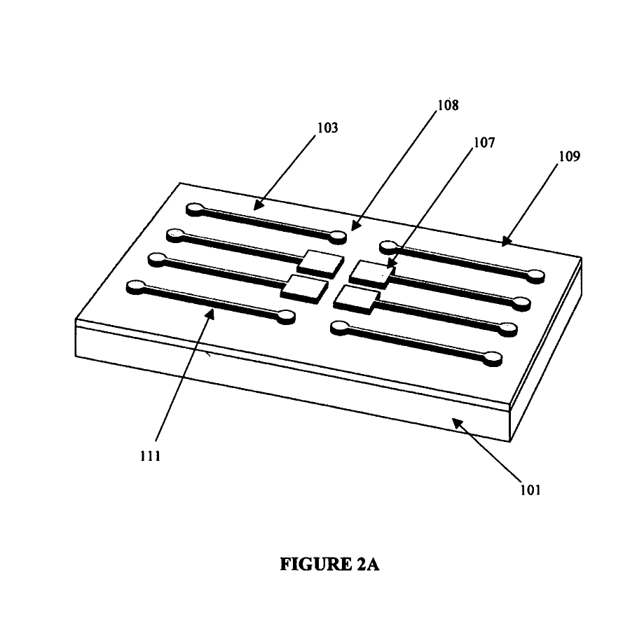

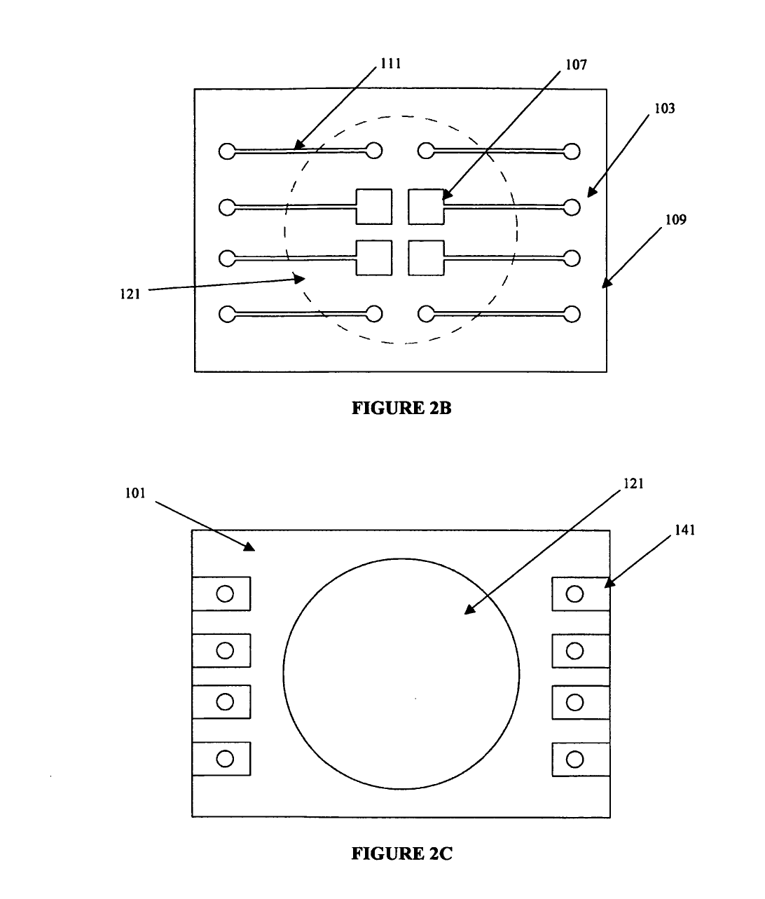

In one embodiment, as illustrated in FIG. 2A, a substrate can comprise two components, namely a carrier portion 101 and a thermally conductive portion 109. In one embodiment the carrier portion can be silicon upon which is formed a thin layer CVD diamond, wherein the CVD diamond layer can allow thermal spreading of heat laterally and can provide a means for heat transfer to a thermally conductive element in intimate thermal contact thereto. As illustrated in FIGS. 2B and 2C, the underside of the silicon can be etched in order to create a circular pattern or blind bore 121 proximate to where the light-emitting elements are positioned on the CVD diamond. This blind bore can serve as a sleeve for the insertion of a heat pipe that can provide a means for removal of the heat generated by the light-emitting elements.

With further reference to FIGS. 2A and 2B, bond pads 107 and 108 can be positioned on the substrate and can provide positions upon which one or more light-emitting elements can be connected and optionally one or more sensors can be connected. As illustrated, direct or indirect electrical connection between the substrate and a power supply and/or controller can be enabled by electrical contacts 141 on the bottom of the substrate. These electrical contacts may be in the form of solder pads, for example. In this configuration, vias 103 and possibly electrical traces 111 on the substrate can be provided for enabling electrical connection of a bond pad to the electrical contact on the bottom of the substrate. Alternately, wrap around connections can be provided to electrical connection to the electrical contact on the bottom of the substrate.

In one embodiment of the present invention bond sites enabling electrical connection of the one or more light-emitting elements or one or more sensors may be provided on the topside of the substrate. These bond sites can provide a means for direct or indirect connection to a power supply and/or controller. In one embodiment, this configuration can provide a means for the substrate to be mounted into a semiconductor or integrated circuit (IC) package including quad flat pack (QFP), overmould ball grid array (BGA), Low profile QFP or quad flat pack no-lead (QFN), for example.

In one embodiment, a portion of the substrate can be etched to create a micro-cooler heat exchanger that can be interfaced with a liquid cooling system or chiller, for example.

### Light-Emitting Elements

The one or more light-emitting elements can be selected to provide a predetermined colour of light. The number, type and colour of the light-emitting elements within the lighting device package may provide a means for achieving high luminous efficiency, a high Colour Rendering Index (CRI), and a large colour gamut, for example. The one or more light-emitting elements can be manufactured using either organic material, for example OLEDs or PLEDs or inorganic material, for example semiconductor LEDs. The one or more light-emitting elements can be primary light-emitting elements that can emit colours including blue, green, red or any other colour. The one or more light-emitting elements can optionally be secondary light-emitting elements, which convert the emission of a primary source into one or more monochromatic wavelengths or quasi-monochromatic wavelengths for example blue or UV pumped phosphor or quantum dot white LEDs or blue or UV pumped phosphor green LEDs or other LED formats known in the art. Additionally, a combination of primary and/or secondary light-emitting elements can be provided within the package, and can be determined based on the desired light output from the lighting device package.

In one embodiment, a lighting device package comprises light-emitting elements having spectral outputs corresponding to the colours red, green and blue can be selected, for example. Optionally, light-emitting elements of other spectral output can additionally be incorporated into the lighting device package, for example light-emitting elements radiating at the red, green, blue and amber wavelength regions or optionally may include one or more light-emitting elements radiating at the cyan wavelength region. Optionally, light-emitting elements emitting colours corresponding to warm white, green and blue can be selected. The selection of light-emitting elements for the lighting device package can be directly related to the desired colour gamut and/or the desired maximum luminous flux and colour rendering index (CRI) to be created by the lighting device package.

In another embodiment of the present invention, a plurality of light-emitting elements are combined in an additive manner such that any combination of monochromatic, polychromatic and/or broadband sources is possible. Such a combination of light-emitting elements includes a combination of red, green and blue (RGB), red, green, blue and amber (RGBA) and combinations of said RGB and RGBA with white light-emitting elements. The combination of both primary and secondary light-emitting elements in an additive manner can be used in the lighting device package. Furthermore, the combination of monochromatic sources with polychromatic and broadband sources such as RGB and white and RGBA and white may also occur in the lighting device package. The number, type and colour of the light-emitting elements can be selected depending on the lighting application and to satisfy lighting requirements in terms of a desired luminous efficiency and/or CRI.

In one embodiment of the present invention the light-emitting elements are substantially closely packed when mounted onto the thermally conductive region of the substrate. This format of light-emitting element positioning can aid in the reduction of the amount of non-radiating surface area imaged or projected through the optical system. In one embodiment of the present invention, the spacing between the light-emitting elements can be less than about twice longest dimension of the light-emitting element.

In another embodiment, the spacing is less than about the longest dimension, and in a further embodiment the spacing is less than about half the longest dimension. In one embodiment the spacing between the light-emitting elements is about 100 μm.

In one embodiment of the present invention, the light-emitting elements of the lighting device package are arranged to have a relatively small chromaticity momentum. The chromaticity momentum can be determined as the sum of the products of luminous flux and distance to the optical axis for each chromaticity of the light-emitting elements in the lighting device package.

### Optical System

The lighting device package comprises an optical system enabling light extraction from the light-emitting elements to which it is optically coupled. The optical system can be formed from one or more optical elements, encapsulation material, or both one or more optical elements and encapsulation material. An optical element can be a refractive optical element, a reflective optical element, a diffractive optical element or other format of optical element as would be known to a worker skilled in the art.

The optical system can be manufactured from one or more of a variety of materials, provided that the material has desired optical and mechanical characteristics for the specific lighting device package. For example the optical system can be manufactured from one or more of polycarbonate, glass, acrylic, silicone, metal or alloy, reflectively coated plastic or any other material as would be readily understood by a worker skilled in the art.

In one embodiment, the optical system can include one or more refractive elements, for example, a dome lens, or a micro-lens array having one lenticular element per each or more light-emitting elements or a micro-lens array having more than one lenticular element for each light-emitting element. The refractive element can be a solid glass or plastic or a fluid optical element. Furthermore the primary optical system can also comprise one or more diffractive or holographic elements, or one or more diffusive or specular reflective elements.

In one embodiment of the present invention, the optical system comprises a dome lens having a spherical or aspherical shape. The light emitting surfaces of the one or more light-emitting elements of the lighting device package are positioned in order that these light emitting surfaces are located at substantially the centre of curvature of the dome lens.

In one embodiment of the present invention, the exit aperture of the optical system is optimized to achieve substantially high light extraction efficiency for a small exit aperture size. For example, reducing the size of the exit aperture of the optical system can provide a means for colour mixing and beam collimation.

In one embodiment of the present invention, the optical system comprises a combination of one or more reflective optical elements and one or more refractive optical elements.

In one embodiment the optical system can be an index matching encapsulation material. To improve light extraction, the light-emitting elements can be encapsulated in a transparent encapsulation material with a predetermined optical refractive index. For example, the encapsulation material can have a refractive index of about 1.4 to 2 or higher. The optical refractive index of the material can be chosen to substantially match the index of refraction of, for example, the light-emitting elements. However, commercially available encapsulation material with suitable optical properties typically exhibit refractive indices of about 1.4 to 1.6, which can be lower than the refractive indices of the materials used to manufacture light-emitting elements, for example semiconductor materials. Alternatively the encapsulation material can have a predetermined thickness and optical refractive index to increase light extraction. The surface of the die can be coated with a layer of encapsulation material of a determined thickness and optical refractive index creating an anti-reflective coating comparable to anti-reflective coatings used in optics manufacturing.

In one embodiment of the present invention, the refractive index of the encapsulation material is matched to the refractive index of the optical system with which it is in contact.

In another embodiment of the present invention, the refractive index of the encapsulation material is selected to be between the refractive index of the light-emitting elements and the optical system with which it is in contact.

In one embodiment the encapsulation material forms the optical system and can be patterned or textured, for example, sanded, embossed, stamped, or otherwise structured or micro-structured. This texturing or patterning of the encapsulation material can provide a means for increasing light extraction from the light-emitting elements, in addition to light redirection.

In one embodiment of the present invention, the encapsulant or encapsulation material forms the optical system and can be patterned with curved section, pyramidal structures, dimples or any other pattern as would be known to a worker skilled in the art.

In one embodiment the encapsulation material may be shaped like a dome lens or a micro-lens array by a stamping, casting or moulding process.

In one embodiment of the present invention, the lighting package further comprises one or more secondary optical elements that can provide a means for further manipulating the illumination generated by the light-emitting elements. A secondary optical element can provide a means for re-directing the illumination in a desired direction and/or can provide a means for blending the illumination generated by the light-emitting elements or a combination thereof.

Secondary optical elements can include one or a combination of diffractive, refractive, or reflective optics in order to extract the light from the one or more light-emitting elements, or mix the illumination to form a uniform colour, or manipulate the optical output of the lighting package or any combination thereof. Forms of optical elements can include various types of collectors, lenses, reflectors, filters, diffusers or other optical elements as would be readily understood by a worker skilled in the art. Furthermore a secondary optical element may be a liquid lens, GRIN lens and or a stepped compound parabolic collector, for example. A worker skilled in the art would readily understand a variety of optical elements that may be used in the light device package and the selection thereof may be directly related to the configuration and type of the one or more light-emitting elements and the desired illumination to be generated.

### Sensors

In one embodiment, the lighting device package comprises one or more sensors, wherein the one or more sensors are disposed on the substrate and provide a means for collecting information representative of operating conditions of the one or more light-emitting elements and for relaying said information to a controller. For example the one or more sensors can be optical sensors, thermal sensors or pressure sensors.

In one embodiment of the present invention, one or more optical sensors can provide a means for collecting information relating to the output of the one or more light-emitting elements, wherein this information can be quantitative including luminous flux and spectral information, for example wavelength. This information can subsequently be relayed to a controller thereby providing a means for controlling the light-emitting elements in a desired manner thereby producing a desired level and colour of illumination. An optical sensor or photosensor can be selected from a variety of sensors including photodiodes, phototransistors, light-emitting diodes or other optical sensors known in the art.

In one embodiment of the present invention a single broadband optical sensor can be used in the lighting device package, however a multi-colour sensor may optionally be used. Alternately, several narrow band sensors could be used to detect the output of the one or more light-emitting elements.

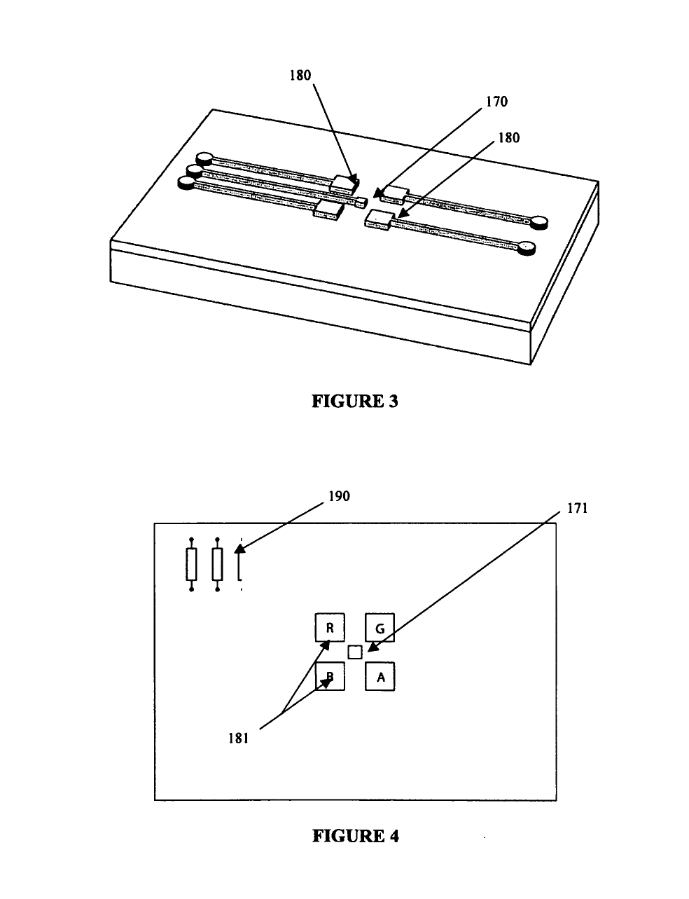

According to one embodiment of the present invention, FIG. 3 illustrates the position of an optical sensor 170 relative to a plurality of light emitting elements 180, wherein each are mounted on a substrate.

In one embodiment, the one or more sensors can be ‘intelligent’ and employ on-board circuitry to condition their output depending on the situation. This type, and other types of circuitry could be incorporated with the one or more sensors to miniaturize or adjust the output of the sensors to better suit the types of light-emitting elements, the type of circuitry, or the type of controller used in the application. For example, photosensors can be integrated with temperature compensation, adjustable gain, and communication capabilities.

It would be readily understood that the collected information relating to the operation of the light-emitting elements can be directly related to the types of light-emitting elements in the lighting device package and additionally related to the form of optical sensor being used. For example for a lighting device package comprising an RGB light-emitting element configuration and a multi-colour optical sensor, during collection similar light-emitting elements may be pulsed in order to collect information relating to the optical characteristics of each colour of light emitting element. Alternately, if several narrow band sensors are used, optical collection relating to the three colours of light-emitting elements can occur simultaneously. As would be readily understood, filters or other optical manipulation techniques can be used to provide a means for collection of information relating to the operation of the various colours of the light-emitting elements. As would be readily understood, the size, position, and orientation of the one or more optical sensors could be different depending on the application and the information desired.

In one embodiment of the present invention, one or more thermal sensors can provide a means for collecting information relating to the operation of the one or more light-emitting elements in the lighting device package, wherein this information can provide a means for determining the operating temperature of the one or more light-emitting elements. This information can subsequently be relayed to a controller thereby providing a means for controlling the light-emitting elements in a desired manner based on the operational temperatures thereof.

In one embodiment, a thermal sensor may comprise a semiconductor diode junction, a band gap reference circuit or any other thermal sensing element used in the integrated circuit art. The one or more thermal sensors can be positioned in order to detect the temperature of the thermally conductive region of the support member as a whole, or alternately a thermal sensor can be positioned proximate to a specific light-emitting element in order to collect thermal information of a more specific nature.

According to one embodiment of the present invention, FIG. 4 illustrates the position of a thermal sensor 190 and optical sensor 171 relative to a plurality of light emitting elements 181, wherein each are mounted on a substrate.

As would be readily understood the operating temperature of a light-emitting element can affect the luminous flux output in addition to the spectral output of a light-emitting element and therefore collecting information relating to the operational temperatures of a light-emitting element can enable more accurate control thereof thereby providing a means for creating a desired output therefrom.

In one embodiment, a thermal sensor may further be used as a safety feature, for example a thermal sensor can be used to protect a light-emitting element from overheating that can lead to premature damage of the light-emitting element.

In another embodiment, the thermal sensor is used to measure the temperature of the light-emitting elements, and adjust the output of the light-emitting elements according to calibration factors, in order to maintain a certain ratio of overall light output, for example to maintain a particular a white point.

### Electronic Components

In one embodiment of the present invention, the lighting device package further comprises additional electronic components, for example integrated circuits (IC), resistors, capacitors, or other components that may provide additional features that can provide a means for collecting, manipulating or relaying information relating to the operational characteristics of the light-emitting elements to a controller. These additional electronic components may be mounted on, under or within the substrate. In one embodiment of the present invention a controller for controlling the functionality of one or more of the light-emitting elements can be integrated into the lighting device package.

In one embodiment, the substrate provides a means for connectivity to one or more thermally conductive elements, thereby it can additionally provide a means for cooling or regulating the operational temperature of these additional electronic components. Therefore, temperature sensitive electronic components that may improve the functionality of the lighting device package, for example an internal controller, may be disposed on the substrate of the lighting device package of the present invention, as thermal management and thermal regulation can be provided.

The invention will now be described with reference to specific examples. It will be understood that the following examples are intended to describe embodiments of the invention and are not intended to limit the invention in any way.

### EXAMPLES

### Example 1

With further reference to FIG. 1 which illustrates a lighting device package according to one embodiment of the present invention. The lighting device package comprises a substrate 110 configured as a thermally conductive substrate, to which is thermally connected light-emitting elements 115. The lighting device package further comprises an optical system formed from a dome shaped lens 125 and an encapsulation material or encapsulant 120, wherein the optical system substantially encloses the light-emitting elements 115. In one embodiment, the dome lens 125 can be mounted onto the substrate 110 using an adhesive such as silicone or a thermally or UV curable epoxy or other adhesive known to a worker skilled in the art. The outer dome surface of the dome lens can provide a means for relatively high extraction efficiency by reducing Fresnel reflections. Antireflection coating of the outer surface of the dome lens can further increase extraction efficiency provided by the optical system.

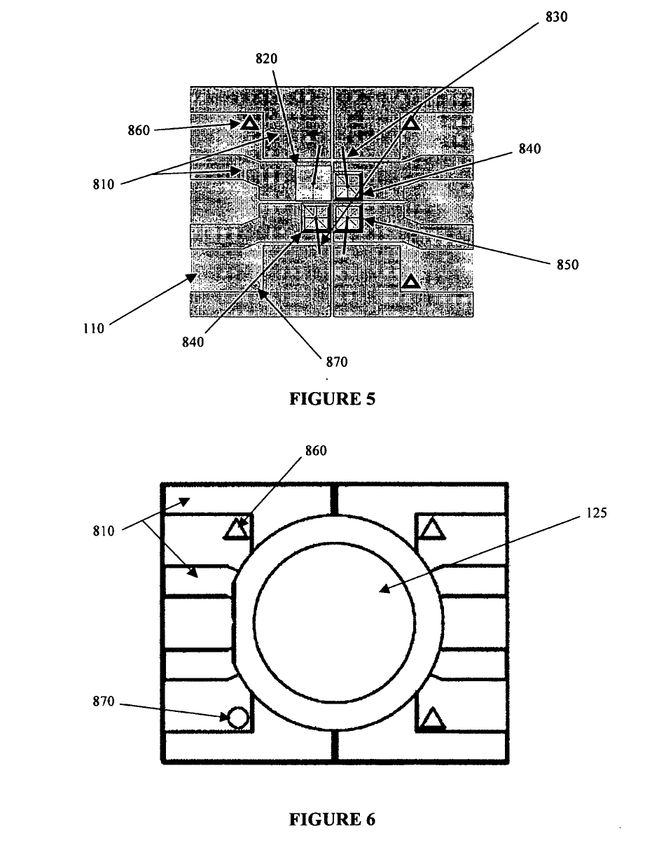

FIG. 5 illustrates the substrate 110 with circuit traces 810 which provide electrical connection to the light-emitting elements, 820, 840 and 850 according to one embodiment of the present invention. Each of the light-emitting elements are mounted on a particular first circuit trace and provided with a circuit bond 830 to a second circuit thereby providing independent electrical connection to each of the light-emitting elements. Also illustrated are fiducials 860 and pin 1 870. Pin 1 can be used for orientation during assembly of the lighting device package and may also be used for test purposes, for example. The fiducials can be provided for machine visions systems an can provide a means for precise orientation and position information relating to the package for fabrication thereof.

In one embodiment of the present invention and with further reference to FIG. 5, light-emitting elements 840 are emit green light, light-emitting element 820 emits red light and light-emitting element 850 emits blue light. Alternate light-emitting element configurations, relating to the number of light-emitting elements and colours of light-emitting elements, would be readily understood by a worker skilled in the art. The alternate configurations can be dependent on the desired colour gamut of the lighting device package and/or the desired luminous flux output desired for the lighting device package, for example.

FIG. 6 illustrates the substrate with circuit traces of FIG. 5, wherein light-emitting elements 820, 840 and 850 are centred under to dome shaped lens 125.

In one embodiment, the light emitting surfaces of the light-emitting elements are positioned to be substantially aligned with the centre of curvature of the dome lens.

In one embodiment, the substrate can be configured to be less than about twice the thickness of the light-emitting elements and the spacing between the light-emitting elements can be less than about half of the longest dimension thereof. In one embodiment the spacing between the light-emitting elements is about 100 μM.

In this embodiment the space between the light-emitting elements 115 and the dome lens 125 is filled with the encapsulant 120, such as an optical silicone, for example. The encapsulant 120 can have an index of refraction as close as possible to the light-emitting elements to enhance light extraction. Typically the refractive index of commercially available silicones for this type of application is in the order of about 1.4 to 1.6. In one embodiment, the dome lens can be held in position through adhesion with the encapsulant 120 rather than or in addition to being adhered to the substrate.

In one embodiment, the refractive index of the encapsulation material can be matched to the refractive index of the dome lens.

Electrical traces may be disposed on the thermally conductive substrate to provide electrical connection to the light-emitting elements. Electrical pads on the edge of the thermally conductive substrate can provide for the electrical and mechanical interfaces and can correlate to electrical pads provided on a carrier, for example a printed circuit board (PCB).

The lighting device package may be coupled to a carrier 105, for example a PCB, wherein the coupling can be provided on the top or bottom of the carrier, for example. In the embodiment where the lighting device package is mounted on top of a carrier, electrical connection to the carrier can be provided by wrap around connections or vias, for example.

A secondary optic (not shown) may be mounted onto the dome lens 125 at location 100 which may provide ease of connection therebetween.

A thermally conductive element can be positioned in intimate thermal contact with the substrate, wherein this intimate thermal contact may be enhanced via thermally conductive epoxy, grease or solder, for example, thereby providing a thermal path to conduct heat away from the light-emitting elements in the lighting device package.

In one embodiment, one or more sensors or other electronic components can be mounted on the substrate either inside or outside the cavity provided by the dome lens. For example, the one or more sensors can provide information relating to the operating conditions of the light-emitting elements, for example, operational temperature or luminous flux output, chromaticity of the emitted light or other information as would be readily understood by a worker skilled in the art.

### Example 2

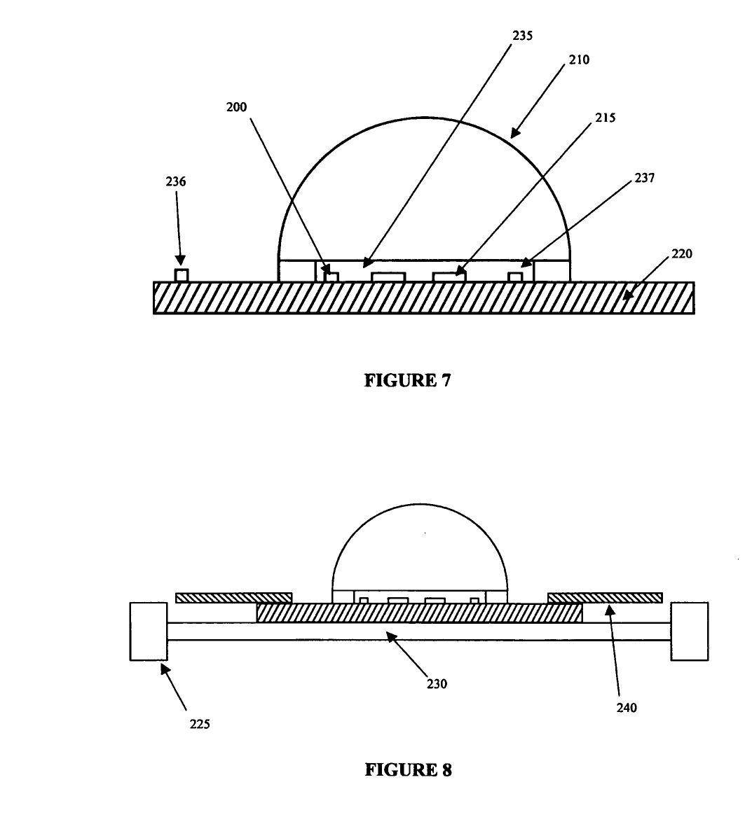

FIG. 7 illustrates a lighting device package according to another embodiment of the present invention. The lighting package comprises a substrate 220 formed as a thermally conductive substrate, upon which is mounted light-emitting elements 215 and optical sensor 200. A half ball lens 210 substantially encloses the light-emitting elements 215 and optical sensor 200 relative to the substrate 220. The region between the half ball lens 210 and the light-emitting elements 215 and optical sensor 200 can be filled with an encapsulation material or encapsulant 235. Optionally, a thermal sensor 236 can be positioned on the substrate 220 outside of the region enclosed by the half ball lens 210. Alternately a thermal sensor 237 may be positioned proximate to the light-emitting elements 215, and therefore may be also be substantially enclosed by the half ball lens 210 relative to the substrate 220.

In one embodiment, the encapsulant can be an index matching fluid or gel, which can substantially match the index of refraction of the light-emitting elements. The encapsulant may increase the amount of light extracted from the lighting device package.

FIG. 8 illustrates a cross section view of the lighting device package illustrated in FIG. 7, wherein the substrate is a thermally conductive member which is thermally coupled to a heat pipe 230 between the two ends thereof. In this embodiment, the heat pipe can transmit the heat away from the light-emitting elements towards one or both of its ends wherein a heat sink or heat dissipation system 225 can be connected in order to dissipate the heat. One or more PCB boards 240 can be positioned proximate to the substrate thereby enabling additional electronic components to be coupled to the lighting device package though one or more of a variety of known electrical coupling mechanisms.

### Example 3

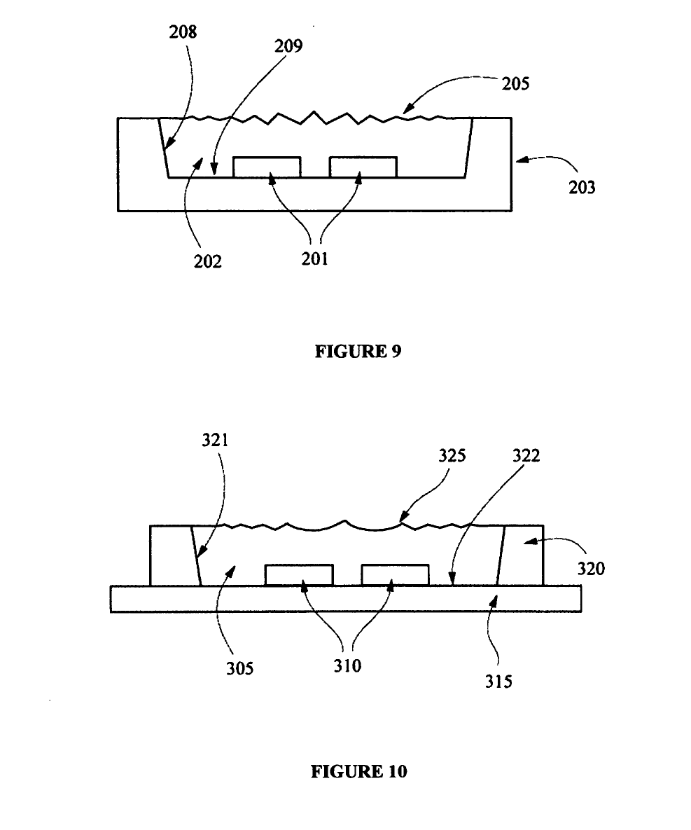

FIG. 9 illustrates another example of a lighting device package according to one embodiment of the present invention. The substrate 203 is formed with a depression therein, wherein the light-emitting elements 201 can be thermally connected to the substrate within the depression. The side-walls 208 and the top 209 of the substrate can be configured to be optically active, for example reflective which can provide a means for additional light extraction form the light-emitting elements and may also provide a means for reducing re-absorption of the emitted light by the light-emitting elements. The side-walls 208 and the top 209 of the substrate can be specular or diffuse reflective or may comprise sections that are specular and diffuse reflective. The lighting device package further comprises an encapsulation material or encapsulant 202 comprising an embossed or pattered surface 205. This surface patterning can provide a means for redirecting light from the die and can also provide a means for coupling the light into the air outside of the lighting device package.

In one embodiment of the present invention, the optical system, namely the side-walls 208, the top 209 of the substrate and the encapsulant 202, associated with this lighting device package can be configured to redirect light away from the light-emitting elements, thereby reducing re-absorption of the light by the light-emitting elements.

### Example 4

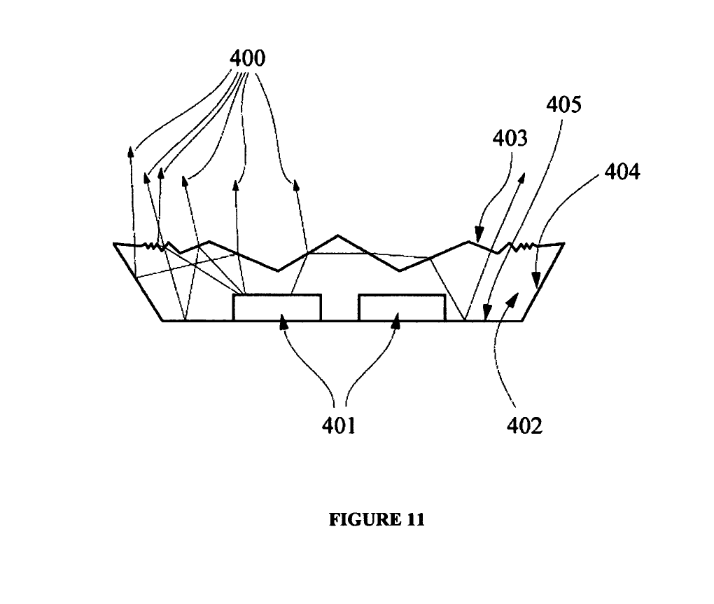

FIG. 10 illustrates a lighting device package according to another embodiment of the present invention, wherein the optical system is a combination of reflective perimeter walls 320 which are mounted around the light emitting elements 310, and an encapsulation material or encapsulant 305 with a patterned emitting surface 325. The sidewalls 321 of the perimeter walls 320 and the top 322 of the substrate can be optically active, for example to reflect the light emitted by the light-emitting elements 310 in order to improve light extraction from the lighting device package. The side-walls 325 of the perimeter walls and the top 322 of the substrate can be specular or diffuse reflective or may comprise sections that are specular and diffuse reflective. The thermally conductive substrate 315 can be formed as a planar structure, for example. The lighting device package according to this embodiment can function similar to that as described for FIG. 9.

FIG. 11 illustrates potential interactions of light emitted by the light-emitting elements 401 with an optical system formed according to one embodiment of the present invention. Base surface 405 and side surfaces 404 can be reflective and the surface of the exit aperture can be patterned 403. The lighting device packages according to FIG. 9 or 10 may produce the potential light interactions as illustrated in FIG. 11.

### Example 5

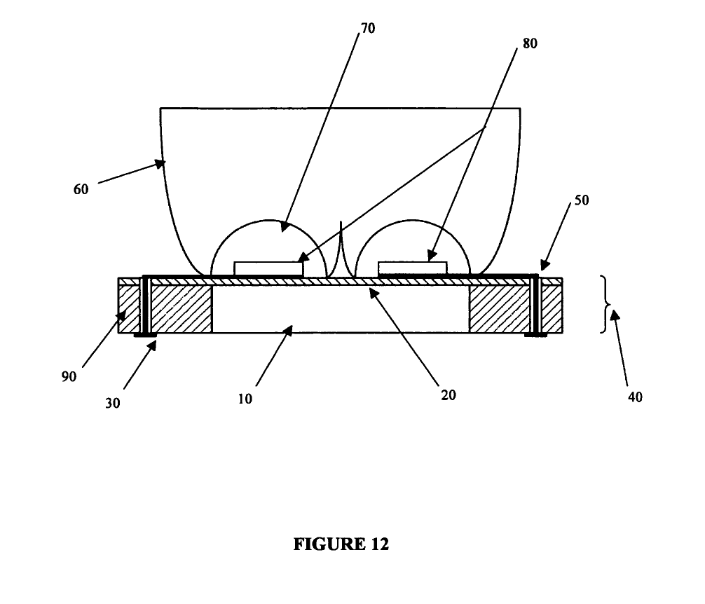

One embodiment of a lighting device package according to the present invention is illustrated in FIG. 12. The substrate 40 comprises two components, namely a carrier portion 90 and a thermally conductive portion 20. Upon the substrate are disposed light-emitting elements 80 in thermal contact with the thermally conductive portion 20 of the substrate 40. The light-emitting elements can be electrically connected using traces and vias 50, to bond positions 30 on the bottom of the substrate. Furthermore the substrate is configured to enable intimate thermal contact between a thermally conductive element (not shown) and the thermally conductive portion 20 of the substrate, thereby providing a thermal path for heat removal away from the light-emitting elements 80. In this embodiment the thermally conductive element can be a heat pipe and the substrate can be constructed with a blind bore 10 for receiving the heat pipe therein. The blind bore however, is not specifically required, however it can be advantageous in that it can reduce the thermal resistance between the light-emitting elements and the heat pipe and may additionally provide mechanical stability.

In this embodiment, optics can be positioned over the light-emitting elements, wherein the optics can include a moulded compound parabolic collector (CPC) lens 60 with an integrated holographic diffuser. In one embodiment, the CPC lens can be configured to surround each of the light-emitting elements individually or can be configured to surround all of the light-emitting elements together. Furthermore, the holographic diffuser and the CPC lens can be designed to reduce the overall length and size of the optics, while providing a desired level of light mixing of the light emitted by each of the light-emitting elements.

In addition an index matching substance 70, for example a fluid or gel, can used to encapsulate the light-emitting elements. This format of optic can enable a high level of light extraction from the light-emitting elements in addition to the mixing of different colours of light emitted by the light-emitting elements in order to form a desired colour of light, for example white light. The lighting device package further comprises one or more sensors (not shown), for example optical or thermal sensors. An optical sensor can be used to determine the luminous flux generated by the light-emitting elements and a thermal sensor can be used to evaluate the operating temperature of the light-emitting elements.

### Example 6

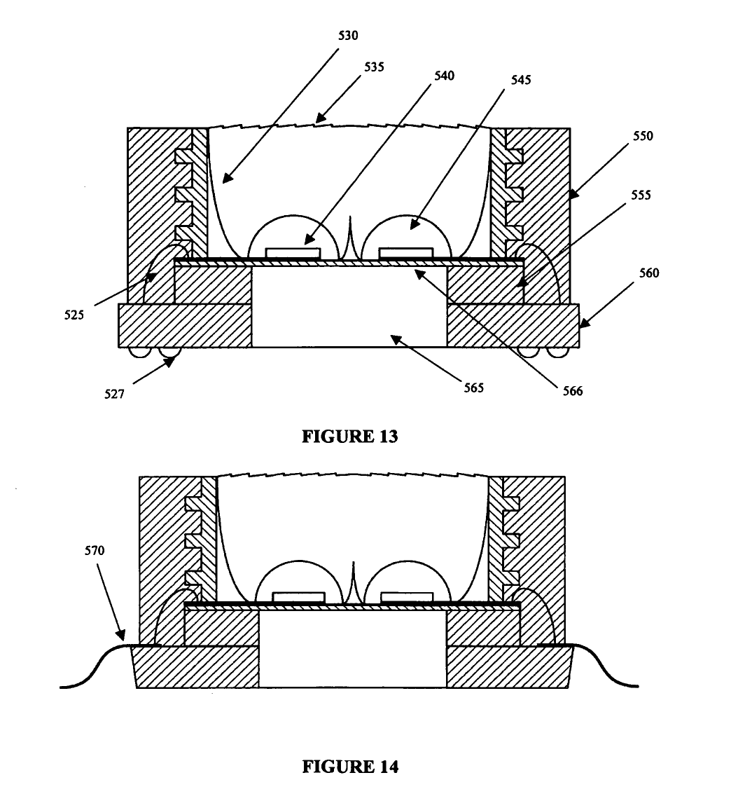

FIG. 13 illustrates a lighting device package according to one embodiment of the present invention, wherein the lighting device package is formed as a ball grip array (BGA). This lighting device package comprises a BGA carrier 560, upon which is mounted a substrate including a silicon layer 555 and a CV diamond thermally conductive layer 566. The light-emitting elements 540 are mounted on the CV diamond layer and are encapsulated by an index matching gel 545. A CPC optic 530 enables for the manipulation of the light generated by the light-emitting elements, and this light is subsequently directed towards a diffuser or lens 535. This form of package can be encased in an epoxy resin 550, for example. The light-emitting elements can be electrically connected to wire bends 525 which can provide a means for the electrical connection of the light-emitting elements to solder points 527 on the underside of the BGA carrier though vias within the BGA carrier, for example. As is illustrated in FIG. 13, a blind hole 565 is provided within both the BGA carrier and the silicon layer 555 of the substrate in order to provide an insertion location for a heat pipe. FIG. 14 illustrates a modification of the embodiment illustrated in FIG. 13, such that it is configured as a quad flat pack (QFP), wherein secondary wire bends 570 are provided to enable electrical connection from the QFP carrier to a proximate PCB board, for example.

### Example 7

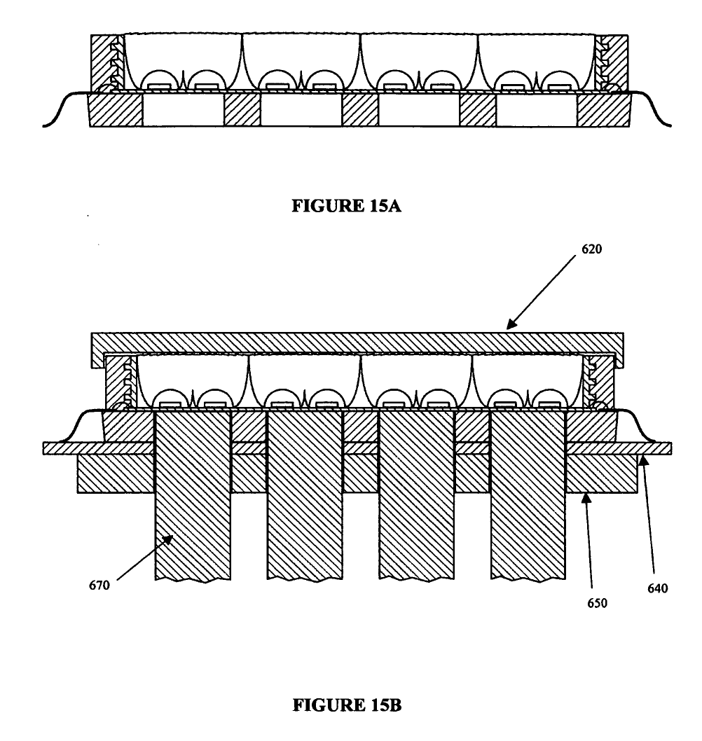

FIG. 15A illustrates a lighting device package according to another embodiment of the present invention, wherein the single configuration as illustrated in FIG. 14, is configured as a quad flat pack (QFP) package. Furthermore, FIG. 15B illustrates the embodiment of FIG. 15A with integrated heat pipes 670, a PCB board 640, for example a FR4 board which is positioned between the QFP package and a support structure 650 for positioning and supporting the heat pipes. In this embodiment the light-emitting elements are electrically connected to the PCB board which can have additional electronic components mounted thereon, for example a controller. A tertiary optic 620 can additionally be provided and can be for example snapped onto the package. This tertiary optic can enable further manipulation of the light emitted from the lighting device package, for example further light mixing.

As illustrated in the Figures, the sizes of layers or regions are exaggerated for illustrative purposes and, thus, are provided to illustrate the general structures of the present invention. Once again, as stated previously, various aspects of the present invention are described with reference to a layer or structure being formed on a substrate or other layer or structure.

It is obvious that the foregoing embodiments of the invention are exemplary and can be varied in many ways. Such present or future variations are not to be regarded as a departure from the spirit and scope of the invention, and all such modifications as would be obvious to one skilled in the art are intended to be included within the scope of the following claims.

The disclosure of all patents, publications, including published patent applications, and database entries referenced in this specification are specifically incorporated by reference in their entirety to the same extent as if each such individual patent, publication, and database entry were specifically and individually indicated to be incorporated by reference.

We claim:

1. A lighting device package comprising:
a) a substrate including a thermally conductive region;
b) one or more light-emitting elements mounted on the substrate to provide thermal connectivity between the one or more light-emitting elements and the thermally conductive region, the one or more light-emitting elements for generating light; and
c) an optical system coupled to the substrate and configured to substantially enclose the one or more light-emitting elements on the substrate, the optical system adapted to extract the light from the one or more light-emitting elements;
wherein the lighting device package is adapted for connection to a means for controlling activation of the one or more light-emitting elements.

2. The lighting device package according to claim 1, wherein the thermally conductive region is adapted for intimate thermal connection to a thermally conductive element.

3. The lighting device package according to claim 2, wherein the thermally conductive element is a heat sink, heat pipe, thermosyphon, heat exchanger, micro-cooler heat exchanger, thermoelectric, thermotunnel, heat spreader or heat sink.

4. The lighting device package according to claim 2, wherein the intimate thermal connection is by one or more of a thermal grease, thermal transfer film, thermal conductive epoxy and a thermally conductive solder.

5. The lighting device package according to claim 1, wherein the substrate is configured as a thermally conductive substrate.

6. The lighting device package according to claim 1, wherein the substrate includes a carrier portion proximate to the thermally conductive region, the carrier portion configured to expose the thermally conductive region for thermal access thereto.

7. The lighting device package according to claim 6, wherein the carrier portion is etched to create a micro-cooler heat exchanger.

8. The lighting device package according to claim 1, wherein the substrate has a central region, said central region is formed as a depression, said central region having side walls wherein the side walls are optically active.

9. The lighting device package according to claim 1, wherein the substrate comprises circuit traces providing electrical connections to the one or more light-emitting elements.

10. The lighting device package according to claim 1, further comprising one or more sensors mounted onto the substrate.

11. The lighting device package according to claim 10, wherein the one or more sensors is an optical sensor.

12. The lighting device package according to claim 10, wherein the one or more sensors is a temperature sensor.

13. The lighting device package according to claim 10, wherein the one or more sensors are substantially enclosed by the optical system.

14. The lighting device package according to claim 1, wherein the optical system is formed from one or more of reflective optical element, refractive optical element, diffractive optical element and encapsulation material.

15. The lighting device package according to claim 14, wherein the optical system is a refractive optical element formed as a dome lens or a micro-lens array.

16. The lighting device package according to claim 15, wherein the dome lens is spherical or aspherical.

17. The lighting device package according to claim 16, wherein each of the one or more light-emitting elements has a light emitting surface and the dome lens has a curvature having a centre, and wherein the light emitting surface is positioned at the centre of curvature.

18. The lighting device package according to claim 15, wherein encapsulation material fills a space between the one or more light-emitting elements and the dome lens.

19. The lighting device package according to claim 1, wherein the optical system is an encapsulation material is patterned or textured.

20. The lighting device package according to claim 18, wherein the encapsulation material is stamped, sanded, embossed or micro-structured.

21. The lighting device package according to claim 1, further comprising secondary optical elements configured to mate with the optical system.

22. The lighting device package according to claim 21, wherein the secondary optical elements are one or more of diffractive optics, refractive optics or reflective optics.
